(19) United States
(12) Patent Application Publication
(10) Pub. No.: US 2017/0069518 A1
(43) Pub. Date: Mar. 9, 2017

(54) ELECTROSTATIC SUBSTRATE HOLDER WITH NON-PLANAR SURFACE AND METHOD OF ETCHING

(71) Applicant: GLOBALFOUNDRIES INC., Malta, NY (US)

(72) Inventors: Brett Cucci, Callicoon, NY (US); Thai Doan, Burlington, VT (US); Jeffrey P. Gambino, Portland, OR (US); Rebecca K. Kelley, Essex Junction, VT (US); Jed H. Rankin, Richmond, VT (US); Daniel S. Vanslette, Fairfax, VT (US)

(21) Appl. No.: 14/845,896

(22) Filed: Sep. 4, 2015

(51) Int. Cl. H01L 21/683; H01L 21/67; H01L 21/3065

(52) U.S. Cl. CPC H01L 21/6833; H01L 21/3065; H01L 21/67069

(57) ABSTRACT

An apparatus and method of etching. The apparatus including a support substrate having a top surface; a stack of a multiplicity of layers formed on the top surface of the support substrate from a lowermost layer on the top surface of the support substrate to a topmost layer that is furthest from the support substrate; and wherein an entirety of the top surface of the topmost layer is not planar and at least one of the multiplicity of layers that is not the topmost layer is an electrically conductive layer.

### BACKGROUND

The present invention relates to the field of integrated circuits; more specifically, it relates to a substrate holder for a reactive ion etch tool and the method of fabricating integrated circuits using the substrate holder.

When integrated circuit substrates are reactively ion etched, there is a significant degradation of etch quality at the periphery of the substrate resulting in quality and yield loss. Accordingly, there exists a need in the art to mitigate the deficiencies and limitations described hereinabove.

### BRIEF SUMMARY

A first aspect of the present invention is an apparatus, comprising: a support substrate having a top surface; a stack of a multiplicity of layers formed on the top surface of the support substrate from a lowermost layer on the top surface of the support substrate to a topmost layer that is furthest from the support substrate; and wherein an entirety of the top surface of the topmost layer is not planar and at least one of the multiplicity of layers that is not the topmost layer is an electrically conductive layer.

A second aspect of the present invention is reactive ion etch system, comprising: a chamber; means for generating a flux of reactive ions toward a substrate holder placed in the chamber; an edge protection system configured to prevent the reactive ions striking an edge of a wafer placed on the substrate holder; and wherein the substrate holder comprises: a support substrate having a top surface; a stack of a multiplicity of layers formed on the top surface of the support substrate from a lowermost layer on the top surface of the support substrate to a topmost layer that is furthest from the support substrate; and wherein an entirety of the top surface of the topmost layer is not planar and at least one of the multiplicity of layers that is not the topmost layer is an electrically conductive layer.

A third aspect of the present invention is a method comprising: loading a semiconductor wafer unto a substrate holder of a reactive ion etch system, the reactive ion etch system comprising: a chamber; means for generating a flux of reactive ions toward the substrate holder placed in the chamber; an edge protection system configured to prevent the reactive ions striking an edge of the semiconductor wafer on the substrate holder; and wherein the substrate holder comprises: a support substrate having a top surface; a stack of a multiplicity of layers formed on the top surface of the support substrate from a lowermost layer on the top surface of the support substrate to a topmost layer that is furthest from the support substrate; and wherein an entirety of the top surface of the topmost layer is not planar and at least one of the multiplicity of layers that is not the topmost layer is an electrically conductive layer; etching the semiconductor wafer; and unloading the semiconductor wafer from the reactive ion etch tool.

These and other aspects of the invention are described below.

### BRIEF DESCRIPTION OF THE DRAWINGS

The features of the invention are set forth in the appended claims. The invention itself, however, will be best understood by reference to the following detailed description of illustrative embodiments when read in conjunction with the accompanying drawings, wherein:

FIG. 1 is a schematic side view of the change in etch features at the periphery of a substrate during reactive ion etch (RIE);

FIG. 1A is a top view of a semiconductor substrate illustrating the peripheral region where etch quality is degraded;

FIGS. 1B and 1C illustrate, respectively, etched structures in the central and peripheral regions of a semiconductor substrate after RIE;

FIG. 2 is a schematic side view of a semiconductor substrate electrostatically clamped to a substrate holder according to an embodiment of the present invention during RIE;

FIG. 2A is a top view of the substrate holder of FIG. 2 illustrating the peripheral region and central region;

FIGS. 2B and 2C illustrate, respectively, etched structures in the central and peripheral regions of the semiconductor substrate of FIG. 2 after RIE;

FIG. 3 is a schematic side view of a semiconductor substrate electrostatically clamped to a substrate holder according to an embodiment of the present invention during RIE;

FIG. 3A is a top view of the substrate holder of FIG. 3 illustrating the peripheral region and central region;

FIGS. 4A and 4B are side views illustrating alternative profiles for the peripheral regions of substrate holders according to embodiments of the present invention;

FIG. 5 is a schematic side view of a semiconductor substrate electrostatically clamped to a substrate holder according to an embodiment of the present invention during RIE;

FIG. 5A is a top view of the substrate holder of FIG. 5;

FIG. 6 is a cross-section illustrating the layers comprising an exemplary substrate holder according to embodiments of the present invention;

FIG. 7 is a top view of a illustrating cooling channels and substrate lifters of an exemplary substrate holder according to embodiments of the present invention; and

FIG. 8 is a schematic cross-section of an exemplary RIE tool in which substrate holders according to embodiments of the present invention may be used.

### DETAILED DESCRIPTION

One example of a semiconductor substrate is a silicon wafer which is a thin disk of silicon having planar polished top and bottom surface that are parallel to each other. The embodiments of the present invention will be described in reference to silicon wafers and particularly in reference to RIE of through silicon vias (TSVs) in silicon wafers. The term wafer should be understood to apply to silicon wafers in particular and other semiconductor substrates in general. Likewise, the embodiments of the present invention are applicable to RIE of other structures and materials other than silicon.

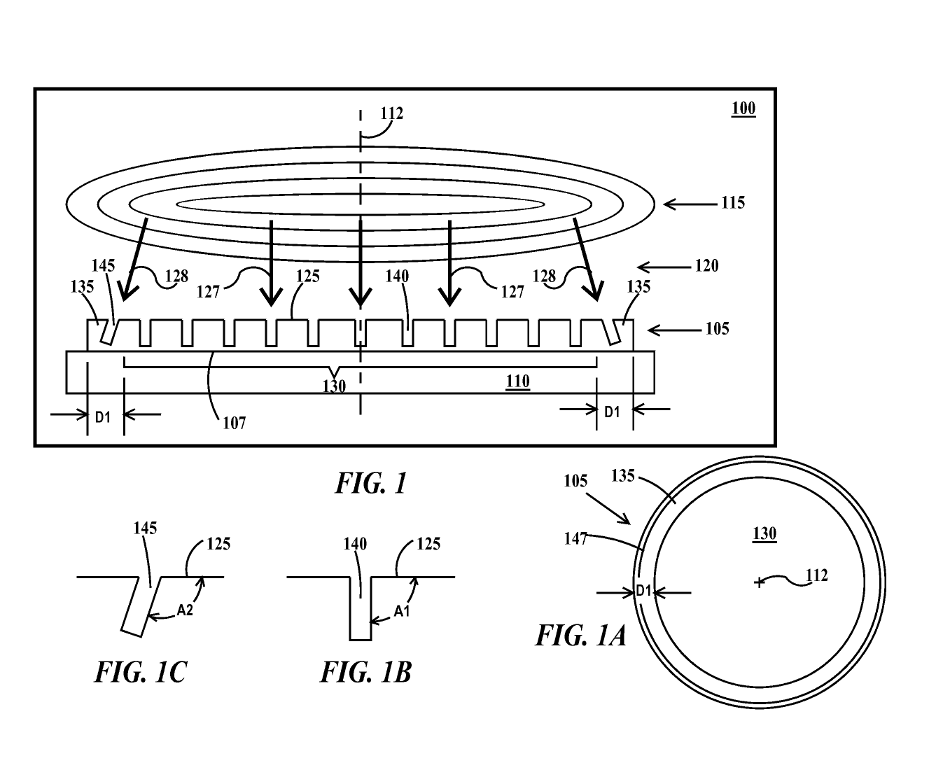

To conventionally RIE a wafer, the wafer is electrostatically clamped on a planar substrate holder having a top surface (the surface that contacts the bottom surface of the wafer) that is a uniformly planar across the entire top surface of the substrate holder. A planar surface is defined as a surface having no greater than 20 μm height difference between any two points on the surface. Reactive ions are formed in a plasma and directed toward the top surface of the wafer being etched. When TSVs are reactively ion etched using a planar substrate holder, TSVs near the edge of the wafer do not etch in a direction perpendicular to the top surface of the wafer, but at a direction that is not perpendicular to the top surface of the wafer (i.e., they are tilted). However, TSVs in the rest of the wafer etch do in a direction predominantly perpendicular to the top surface of the wafer (i.e., in they are not tilted). See description of FIGS. 1, 1A, 1B and 1C infra.

The embodiments of the present invention provide electrostatic substrate holders for RIE that are not uniformly planar across the entire top surface of the substrate holder and are configured to clamp a wafer so as to bend the periphery of the wafer toward its center (the wafer is slightly concave facing the flux of reactive ions) so reactive ions impinge the peripheral region of the top surface of the wafer substantially perpendicular (i.e., at a normal incidence angle) across the entire surface of the substrate not covered by any edge protection system (EPS). The embodiments of the present invention allow etching of non-tilted TSVs closer to the edge of the wafer than currently possible and are compatible with edge protection rings that prevent etching of the bevel at the very edge of the wafer. A benefit of the present invention is improved depth, angle, and TSV structure uniformity from the center to the edge of the wafer.

FIG. 1 is a schematic side view of the change in etch features at the periphery of a substrate RIE. In FIG. 1, a RIE chamber 100 contains a wafer 105 on a top surface 107 of a substrate holder 110. An axis 112 perpendicular to surface 107 passes through the center of wafer 105 and substrate 110. Isopotential lines 115 within the plasma cause ions 120 to be extracted from the plasma. However, all ions 120 do not impinge on the top surface 125 of wafer 105 normal to top surface 125. Ions 127 impinge normal to top surface 125 in a central region 130 of top surface 125 but ions 128 impinge at angle that not normal to top surface 125 in a ring shaped peripheral region 135 of top surface 125.

The direction of travel of ions 127 is parallel to axis 112 while the direction of travel of ions 128 is at an acute angle of less 90° relative to axis 112. The result is TSVs 140 in the central region 130 are not tilted relative to top surface 125 (i.e., they etch at an angle of 0° relative to top surface 125) while TSVs 145 in the peripheral region 135 are tilted relative to top surface 125 (i.e., they are etched at an angle of greater than 0° relative to top surface 125). In one example, for a 200 mm diameter wafer, the tilt angle of TSVs 145 is about 4° and the depth of TSVs 145 is about 25 um less than the depth of TSVs 140. This can cause open or high resistance defects when the TSVs are subsequently filled due to the TSVs (after wafer thinning) not reaching the backside of the wafer or the conductive fill having voids.

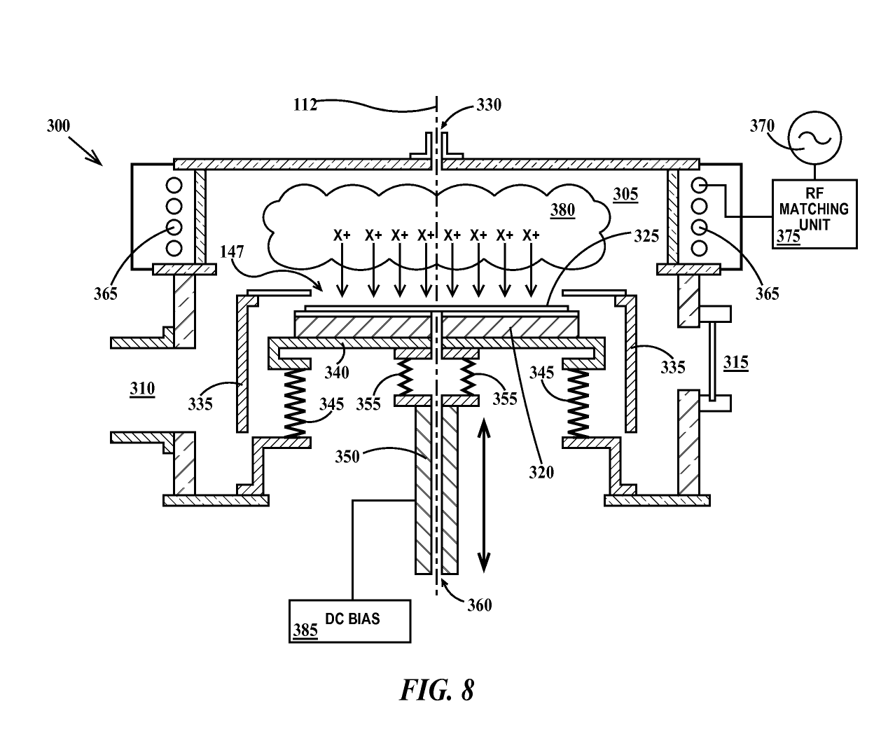

Peripheral region has a width of D1. In one example, for a 200 mm wafer, D1 is about 5 mm. In one example, an edge protective system (EPS) having a circular opening 147 (see description of FIG. 8 infra) overlaps about 1.5 mm of peripheral region 135 closest to the edge of the wafer preventing any etching of the wafer under the EPS.

Dimensions given infra with respect to substrate holders according to embodiments of the present invention are applicable to substrate holders for 200 mm wafers. They may be adjusted for substrate holders for other diameter wafers.

FIG. 1A is a top view of a semiconductor substrate illustrating the peripheral region where etch quality is degraded. In FIG. 1A, the relative positions of central region 130, peripheral region 135, and the edge of opening 147 of the EPS are shown.

FIGS. 1B and 1C illustrate, respectively, etched structures in the central and peripheral regions of a semiconductor substrate after RIE. In FIG. 1B, TSV 140 has sidewalls etched at an angle A1 relative to top surface 125 where A1 is essentially 90°. In FIG. 1C, TSV 145 has sidewalls etched at an angle A2 relative to top surface 125 where A2 is essentially greater than 90°. In one example, for a 200mm wafer, A2 is about 94°.

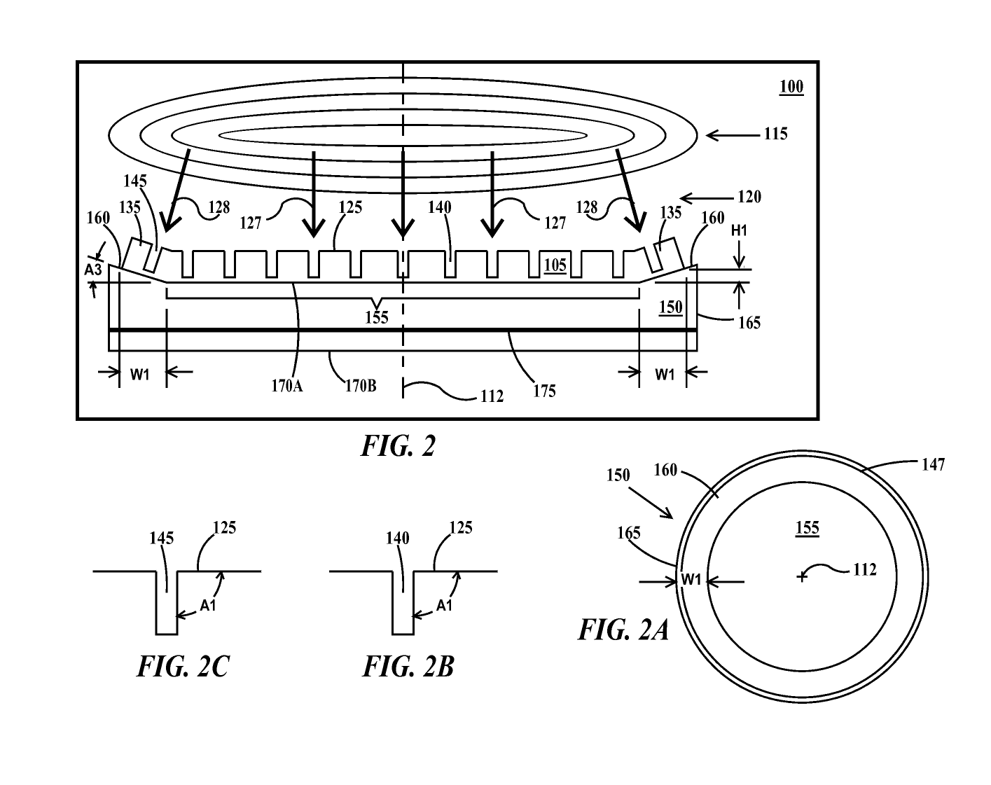

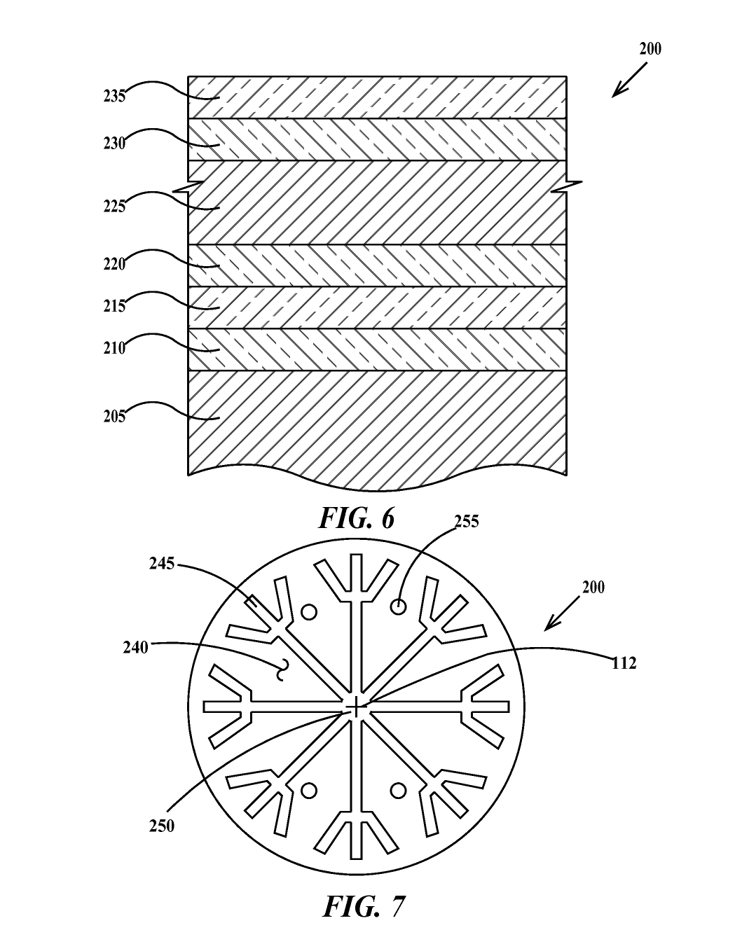

FIG. 2 is a schematic side view of a semiconductor substrate electrostatically clamped to a substrate holder according to an embodiment of the present invention during RIE. FIG. 2 is similar to FIG. 1 except substrate holder 110 of FIG. 1 has been replaced with substrate holder 150. Substrate holder 150 includes a planar central region 155 and an annular ring shaped peripheral region 160 having a flat surface that tilts toward axis 112. Peripheral region 160 of substrate holder 150 is tapered at an angle A3 relative to central region 155 (tilts toward axis 112) from where peripheral region 160 abuts central region to 155 to edge 165 of substrate holder 150. Top surface 170A of substrate holder 155 is perpendicular to axis 112. Thus top surface 170A of substrate holder 155 is not uniformly planar. Top surface 170A is concave and has the shape of an inverted truncated cone that is truncated parallel to the base of the cone. Substrate holder is symmetrical about axis 112. In the example of FIG. 2, the thickness of substrate holder 150 at edge 165 is greater than the thickness of substrate holder 150 in central region 155. However bottom surface 170B may be tapered adjacent to edge 150 so the thickness of substrate holder is the same at any point on the substrate holder. When wafer 105 is electrostatically clamped to top surface 170A, wafer 105 is bent to conform to the topology of top surface 170A. Thus peripheral region 135 of wafer 105 is tilted toward the center of substrate holder 150 so ions 128 impinge essentially normal to top surface 125 of wafer 105. Substrate holder 165 includes an electrically conductive metal layer 175 embedded within the substrate holder that is charged opposite to the charge on wafer 105 to generate the electrostatic clamping force. See the description of FIG. 6 for further description of the layers comprising substrate holders according to embodiments of the present invention. In the example of FIG. 2, electrically conductive metal layer 175 is completely planar and extends parallel to top surface 170A and continues into peripheral region 160.

In one example, A3 is 3° to 5°. In one example, A3 is 3.5° to 4°. The taper of peripheral region 160 is such that bottom surface at edge of wafer 105 is H1 higher than the bottom surface of wafer 105 in central region 130 (see FIG. 1) of wafer 105. The taper of peripheral region 160 is such that the peripheral region 135 of wafer 105 has a width W1. In one example, for a 200 mm wafer, H1 is 2.5 mm to 3.5 mm and W1 is 4 mm to 5 mm.

FIG. 2A is a top view of the substrate holder of FIG. 2 illustrating the peripheral region and central region. In FIG. 2A, the relative positions of central region 155, peripheral region 160, and the edge of opening 147 of the EPS are shown.

FIGS. 2B and 2C illustrate, respectively, etched structures in the central and peripheral regions of the semiconductor substrate of FIG. 2 after RIE. In FIG. 2B, TSV 140 and in FIG. 2C, TSV 145 both have sidewalls etched at angle Al relative to top surface 125 where A1 is essentially 90°.

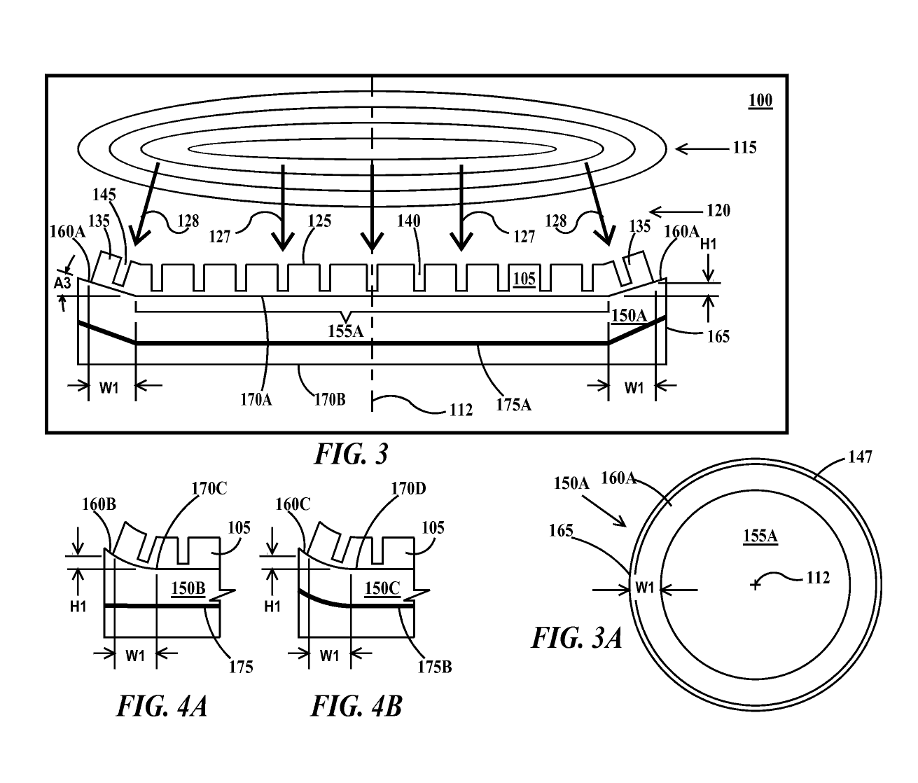

FIG. 3 is a schematic side view of a semiconductor substrate electrostatically clamped to a substrate holder according to an embodiment of the present invention during RIE. FIG. 3 is similar to FIG. 2 except that substrate holder 150A includes an electrically conductive metal layer 175A embedded within the substrate holder. In the example of FIG. 3, electrically conductive metal layer 175A is not completely planar. Electrically conductive layer 175A is only planar under central region 155A but extends parallel to top surface 170A in both central region 155A and annular ring shaped peripheral region 160A having a flat surface. Electrically conductive metal layer 175A follows the contour of top surface 170A. Electrically conductive metal layer 175A is concave and has the shape of an inverted truncated cone that is truncated parallel to the base of the cone. By electrically conductive metal layer 175A following the contour of top surface 170A, the electrostatic clamping force on peripheral regions 135 of wafer 105 is stronger than that applied by electrically conductive metal layer 175A in FIG. 2. FIG. 3A is similar to FIG. 2A.

FIGS. 4A and 4B are side views illustrating alternative profiles for the peripheral regions of substrate holders according to embodiments of the present invention. In FIG. 4A, the straight tapered peripheral region 160 of substrate holder 150 of FIG. 2 is replaced with an annular ring shaped region 160B (having a curved surface) of substrate holder 150B and still include planar electrically conductive metal layer 175. Top surface 170C of substrate holder 150B is concave and has the shape of an inverted spherical segment cut by two parallel planes. In FIG. 4B, the straight tapered peripheral region 160 of substrate holder 150 of FIG. 2 is replaced with an annular ring shaped region 160C (having a curved surface) of substrate holder 150C and still include an electrically conductive metal layer 175B that follows the contour of top surface 170D. Top surface 170D of substrate holder 150C is concave and has the shape of an inverted spherical segment cut by two parallel planes. Likewise electrically conductive metal layer 175B is concave and has the shape of an inverted spherical segment cut by two parallel planes. The dimensions H1, W1 apply to FIGS. 4A and 4B.

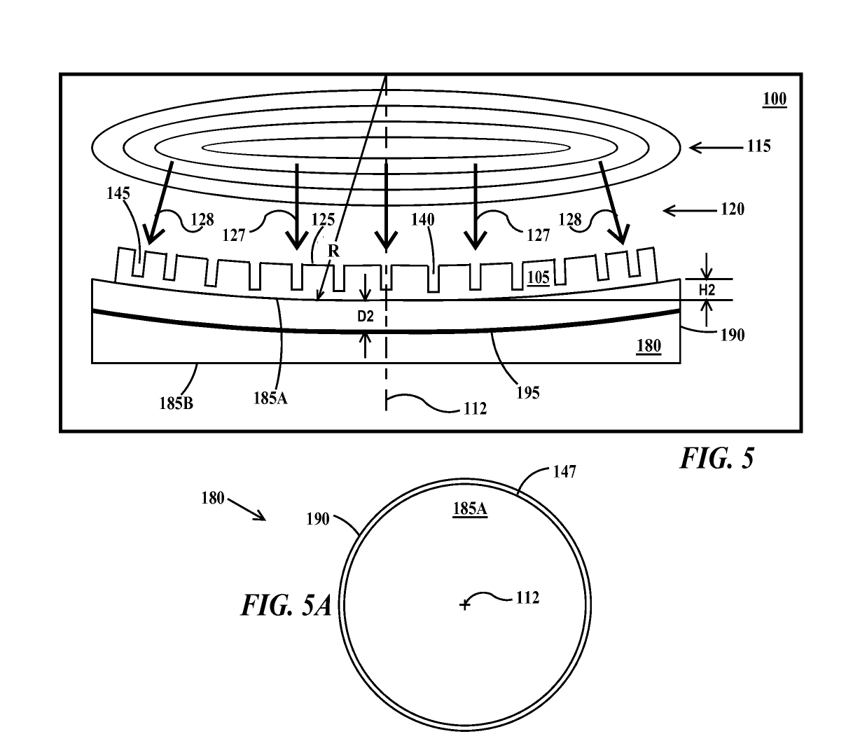

FIG. 5 is a schematic side view of a semiconductor substrate electrostatically clamped to a substrate holder according to an embodiment of the present invention during RIE. FIG. 5 is similar to FIG. 2 except substrate holder 150 is replaced with substrate holder 180. Substrate holder 180 has a uniformly curved top surface 185A, is symmetrical about axis 112, and has a flat bottom surface 185B and an edge 190. Edge 190 is raised a distance H2 above the center of substrate holder 180. Top surface 185A is concave and has the shape of a spherical cap. A spherical cap is that portion of sphere cut off by a plane. Top surface 185A has a radius of curvature R. A radius of curvature is the radius of a circular arc which best approximates a curve at the point it is measured. A circle of radius R has a radius of curvature R which is exact for a spherical cap. In FIG. 5, the radius of curvature is measured from a point on axis 112. Substrate holder 180 includes an electrically conductive metal layer 195. All points on the surface electrically conductive metal layer 195 are a distance D2 from top surface 185A. Electrically conductive metal layer 195 concave and has the shape of a spherical cap and a radius of curvature of R+D2 where D2 is the depth of electrically conductive metal layer 195 below top surface 185A of substrate holder 180. For H2 equal to 0.4 mm, R is approximately 17, 500 mm. In one example, R is 15,000 mm to 20,000 mm. In one example, H2 is in the order 2 mm to 4 mm. In an alternative, bottom surface 185B may also be curved to match the curve of top surface 185A.

FIG. 5A is a top view of the substrate holder of FIG. 5. FIG. 5A illustrates the position of circular opening 147 of an EPS (see description of FIG. 8 infra) relative to top surface 185A of substrate holder 180.

FIG. 6 is a cross-section illustrating the layers comprising an exemplary substrate holder according to embodiments of the present invention. The substrate holders 150 of FIG. 2, 150A of FIG. 3, 150B of FIG. 4A, 150C of FIG. 4B and 180 of FIG.5 may comprise the layers illustrated in FIG. 6. In FIG. 6, substrate holder 200 includes a support substrate 205 formed from aluminum or aluminum alloy. In one example, support substrate is 15 mm to 20 mm thick with 18 mm preferred. Formed on the top surface of support substrate 205 is an anodized layer 210. Anodized layer 210 may be a standard anodized layer or a hard anodized layer. In one example, anodized layer 210 is 5 nm to 15 nm thick. Formed on the top surface of anodized layer 210 is a first adhesive layer 215. In one example, first adhesive layer 215 is a thermo setting adhesive. In one example, first adhesive layer 215 is Scotchbond™ Universal DCA. Adhesive/Dual Cure Activator. In one example, first adhesive layer 215 has a thickness of 0.5 mm to 1.5 mm with 1 mm preferred. Formed on the top surface of first adhesive layer 215 is a first polymer layer 220. In one example, first polymer layer 220 is polyimide. In one example, first polymer layer 220 is 1 mm to 3 mm thick with 2 mm preferred. Formed on the top surface of first polymer layer 220 is an electrically conductive layer 225. Electrically conductive layer 225 is representative of layer as layer 175 (see FIG. 2), layer 170A (see FIG. 3), layer 175B (see FIG. 4B) and layer 195 (see FIG. 5). Electrically conductive layer 225 is not and cannot be the topmost layer. In one example, electrically conductive layer 225 is electroplated copper. In one example, electrically conductive layer 225 is copper or copper alloy foil. In one example, electrically conductive layer 225 is 2.5 μm to 7.5 μm thick with 5 μm preferred. Formed on the top surface of electrically conductive layer 225 is a second adhesive layer 230. In one example, second adhesive layer 230 is a thermo setting adhesive. In one example, second adhesive layer 230 is Scotchbond™ Universal DCA. Adhesive/Dual Cure Activator. In one example, second adhesive layer 230 has a thickness of 0.5 mm to 1.5 mm with 1 mm preferred. Formed on the top surface of second adhesive layer 230 is second polymer layer 235. In one example, second polymer layer 235 is polyimide. In one example, second polymer layer 235 is a polyaryletherketone. In one example, second polymer layer 235 is polyether ether ketone. In one example, second polymer layer is 1 mm to 3 mm thick with 2 mm preferred. In use the bottom surface of wafers to be etched contact the top surface of second polymer 235 and conform to the contour of the top surface of layer 235.

In one example, support substrate 205 may be machined or otherwise formed to have a concave surface to which subsequent layers are applied and conform to generate the topology of top surface170A (see FIG. 2), top surface 170C (see FIG. 4A), top surface 170D (see FIG. 4B) and top surface 185A (see FIG.5). In one example, support substrate is flat and one or more of layers 210, 215, 220, 225, 230 and 235 are formed with a concave surface to generate the topology of top surface 170A (see FIG. 2), top surface 170C (see FIG. 4A), top surface 170D (see FIG. 4B) and top surface 185A (see FIG.5). In one example, only second polymer layer 235 is formed with a concave surface to generate the topology of top surface170A (see FIG. 2), top surface 170C (see FIG. 4A), top surface 170D (see FIG. 4B) and top surface 185A (see FIG.5), the other layers being flat.

Substrate holders 150 (see FIG. 2), 150A (see FIG. 3), 150B (see FIG. 4A), 150C (see FIG. 4B) and 180 (see FIG. 5) according to the embodiments of the present invention are electrostatic chucks of RIE tools. They clamp the wafer to the chuck electrostatically, not by the use of vacuum. Vacuum chucks are not effective because of the low pressure inside of the RIE plasma chambers (see description of FIG. 8 infra). Electrostatic chucks utilize an electrically conductive layer (i.e., layer 225 of FIG. 6) charged positively and separated from the wafer which electrically charged negatively the plasma by an insulator (i.e., second polymer layer 235 of FIG. 6). The wafer, second polymer layer 230 and electrically conductive layer 225 form a capacitor that generates the electrostatic force. Electrostatic chucks of RIE tools are cooled by a backside gas, in one example, helium.

FIG. 7 is a top view of illustrating cooling channels and substrate lifters of an exemplary substrate holder according to embodiments of the present invention. In FIG. 7, substrate holder 200 has a top surface 240 (which is the top surface of second polymer layer 235 of FIG. 6). Substrate holder 200 includes cooling channels 245 open to top surface 240 and connected to a central gas inlet 250 that allow cooling gas to contact the backside of wafers. Substrate holder 200 also includes openings 255 for lifter pins (not shown) for lifting wafers off surface 240 during load/unload operations. In one example, gas inlet 150 goes extends completely through all layers of substrate holder 200 but cooling channels 245 extend continuously only from the top surface 240 through one or more of layers 235, 230, 225, 220, 215 and 210 (see FIG. 6).

Since substrate holder 200 is exemplary, one or more of the layers illustrated may not be present, however electrically conductive layer 225 must be present is not and cannot be the topmost layer of the stack of layers. There must be at least one electrically insulating layer between the top surface of the stack of layers and the top surface of electrically conductive layer and at least one electrically insulating layer between the bottom of electrically conductive layer 225 and any supporting substrate that electrically conductive.

FIG. 8 is a schematic cross-section of an exemplary RIE tool in which substrate holders according to embodiments of the present invention may be used. In FIG. 8, a RIE tool comprises a plasma chamber 305, a vacuum pumping port/exhaust 310, a wafer loading port 315, a substrate holder 320 for holding a wafer 325, a gas inlet 330, an EPS 335, a moveable carrier 340 connected to a first bellows 345, a piston 350 connected to carrier 340 by a second bellows 355 for activating lifter pins (not shown) in substrate carrier 320 and a coolant gas (i.e., He) inlet 360 in piston 350. Substrate holder 320 is representative of substrate holders 150 of FIG. 2, 150A of FIG. 3, 150B of FIG. 4A, 150C of FIG. 4B and 180 of FIG.5. EPS 335 has opening 147 discussed supra. RF coils 365 are connected to a radio frequency (RF) generator370 through an RF matching unit 375 which generates a plasma 380 containing positively and negatively charged ions (FIG. 8 illustrates positive ions X+ being extracted) from reactive gases supplied through gas inlet 330 which ions are accelerated to wafer 325. In one example, for etching silicon, the reactive gas is SF₆. In one example, for etching silicon, the reactive gas is a mixture of SF₆ and O₂. A DC bias unit 385 provides is coupled to the electrically conductive layer 225 (see FIG. 6).

In operation, a wafer is loaded onto the substrate holder and electrostatically clamped to the substrate holder by applying a charge to the conductive layer in the chuck. The wafer bends to conform to the topology of the surface of the substrate holder. The cooling gas is turned on and the plasma chamber pumped down. The reactive gas is turned on and a plasma is struck (i.e., RF turned on). Reactive ions are accelerated toward the surface of the wafer. When etch is complete, the RF is turned off, extinguishing the plasma, the reactive gas turned off, the cooling gas is turned off and the byproducts of the etch are exhausted through the vacuum pump. The electrostatic clamping is turned off, the wafer resumes its normal flat shape and the wafer removed from the chamber.

Thus the embodiments of the present invention provide electrostatic substrate holders for RIE that are not uniformly planar across the entire top surface of the substrate holder and are configured to clamp a wafer so as to bend the periphery of the wafer toward its center (the wafer is slightly concave facing the flux of reactive ions) so reactive ions impinge the peripheral region of the top surface of the wafer substantially perpendicular (i.e., at a normal incidence angle) across the entire surface of the substrate not covered by any EPS that may be present. The embodiments of the present invention allow etching of non-tilted TSVs closer to the edge of the wafer than currently possible and are compatible with edge protection rings that prevent etching of the bevel at the very edge of the wafer.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An apparatus, comprising:
a support substrate having a top surface;
a stack of a multiplicity of layers formed on the top surface of the support substrate from a lowermost layer on the top surface of the support substrate to a topmost layer that is furthest from the support substrate; and
wherein an entirety of the top surface of the topmost layer is not planar and at least one of the multiplicity of layers that is not the topmost layer is an electrically conductive layer.

2. The apparatus of claim 1, wherein the electrically conductive layer extends completely under the top surface parallel to the top surface of the topmost layer and is not planar.

3. The apparatus of claim 1, wherein the wherein the electrically conductive layer extends completely under the top surface of the topmost layer and is planar.

4. The apparatus of claim 1, wherein a central region of the top surface of the topmost layer is planar and an annular ring-shaped peripheral region abutting the central region is not-coplanar with the central region.

5. The apparatus of claim 4, wherein the peripheral region has a flat surface, an inner edge of the peripheral region abutting the central region, an outer edge of the peripheral region raised above top surface of the topmost layer in the central region, the flat surface tilted toward an axis perpendicular to and passing through a center of the support substrate.

6. The apparatus of claim 4, wherein the peripheral region has a curved surface, an inner edge of the peripheral region abutting the central region, an outer edge of the peripheral region raised above top surface of the topmost layer in the central region, the curved surface tilted toward an axis perpendicular to and passing through a center of the support substrate.

7. The apparatus of claim 1, wherein the top surface of the topmost layer is uniformly curved and has a radius of curvature passing through an axis perpendicular to and passing through a center of the support substrate.

8. A reactive ion etch system, comprising:
a chamber;
means for generating a flux of reactive ions toward a substrate holder placed in the chamber;
an edge protection system configured to prevent the reactive ions striking an edge of a wafer placed on the substrate holder; and
wherein the substrate holder comprises:
a support substrate having a top surface;
a stack of a multiplicity of layers formed on the top surface of the support substrate from a lowermost layer on the top surface of the support substrate to a topmost layer that is furthest from the support substrate; and
wherein an entirety of the top surface of the topmost layer is not planar and at least one of the multiplicity of layers that is not the topmost layer is an electrically conductive layer.

9. The reactive ion etch system of claim 8, wherein the electrically conductive layer extends completely under the top surface parallel to the top surface of the topmost layer and is not planar.

10. The reactive ion etch system of claim 8, wherein the wherein the electrically conductive layer extends completely under the top surface of the topmost layer and is planar.

11. The reactive ion etch system of claim 8, wherein a central region of the top surface of the topmost layer is planar and an annular ring-shaped peripheral region abutting the central region is not-coplanar with the central region.

12. The reactive ion etch system of claim 11, wherein the peripheral region has a flat surface, an inner edge of the peripheral region abutting the central region, an outer edge of the peripheral region raised above top surface of the topmost layer in the central region, the flat surface tilted toward an axis perpendicular to and passing through a center of the support substrate.

13. The reactive ion etch system of claim 8, wherein the peripheral region has a curved surface, an inner edge of the peripheral region abutting the central region, an outer edge of the peripheral region raised above top surface of the topmost layer in the central region, the curved surface tilted toward an axis perpendicular to and passing through a center of the support substrate.

14. The reactive ion etch system of claim 8, wherein the top surface of the topmost layer is uniformly curved and has a radius of curvature passing through an axis perpendicular to and passing through a center of the support substrate.

15-20. (canceled)
